(19) United States
(12) Patent Application Publication
(10) Pub. No.: US 2024/0353453 A1
(43) Pub. Date: Oct. 24, 2024

(54) MEASUREMENT DEVICE, SYSTEM AND METHOD, EACH ALLOWING FOR POWER TRACE SYNCHRONIZATION

(71) Applicant: Rohde & Schwarz GmbH & Co. KG, Munich (DE)

(72) Inventor: Dominik BURKERT, Munich (DE)

(73) Assignee: Rohde & Schwarz GmbH & Co. KG, Munich (DE)

(21) Appl. No.: 18/304,160

(22) Filed: Apr. 20, 2023

(51) Int. Cl. G01R 21/00

(52) U.S. Cl. CPC G01R 21/00

(57) ABSTRACT

A measurement device for performing measurements with respect to a device under test with the aid of an apparatus is provided. Said measurement device comprises a trigger transmitter, and a memory comprising a log file. In this context, the trigger transmitter is configured to send a trigger event to the apparatus and to log said trigger event together with a corresponding time stamp in the log file.

### TECHNICAL FIELD

The disclosure relates to a measurement device for performing measurements with respect to a device under test with the aid of an apparatus, a system comprising such a measurement device and such an apparatus, and a method for performing measurements with respect to a device under test with the aid of an apparatus, wherein said device, system and method allow for power trace synchronization.

### BACKGROUND ART

Generally, in times of an increasing number of communication applications, there is a growing need of a measurement device for performing measurements with respect to a device under test with the aid of an apparatus, a system comprising such a measurement device and such an apparatus, and a method for performing measurements with respect to a device under test with the aid of an apparatus in order to test correct functioning of such applications in a particularly accurate and highly efficient manner.

For instance, in the context of displaying measurement data, especially with a high sample rate, from a peripheral measurement device on a main measurement device with other corresponding signal information, synchronization of said data and information is essential to prevent erroneous measurements.

### SUMMARY

Thus, there is a need to provide an improved measurement device, system and method, each allowing for power trace synchronization in order to ensure particularly accurate and highly efficient measurements.

This is achieved by the embodiments provided in the enclosed independent claims. Advantageous implementations of the present disclosure are further defined in the dependent claims.

According to a first aspect of the present disclosure, a measurement device for performing measurements with respect to a device under test with the aid of an apparatus is provided. Said measurement device comprises a trigger transmitter, and a memory comprising a log file. In this context, the trigger transmitter is configured to send a trigger event to the apparatus and to log said trigger event together with a corresponding time stamp in the log file. Advantageously, this allows for power trace synchronization. Further advantageously, the measurement device can have a sample rate of at least 500 kilosamples per second or at least 1 megasample per second.

According to an implementation form of the first aspect of the present disclosure, the trigger event is sent on the basis of and/or with the aid of a trigger signal. Advantageously, for instance, the measurement device can comprise an output or an output port, respectively, for providing said trigger signal.

According to a further implementation form of the first aspect of the present disclosure, the trigger signal comprises or is an analog trigger signal. Advantageously, for example, the above-mentioned output or output port, respectively, can be an analog output or an analog output port, respectively.

According to a further implementation form of the first aspect of the present disclosure, sending the trigger event to the apparatus and logging said trigger event together with a corresponding time stamp in the log file are performed simultaneously. Advantageously, for instance, not only accuracy but also efficiency can further be increased.

According to a further implementation form of the first aspect of the present disclosure, the measurement device further comprises a power consumption monitor. In this context, the power consumption monitor is configured to notify the trigger transmitter to send the trigger event to the apparatus in intervals and to log the trigger event together with the corresponding time stamp in the log file. Advantageously, for example, a drift of a corresponding clock or oscillator of the apparatus can be corrected.

According to a further implementation form of the first aspect of the present disclosure, the power consumption monitor is configured to control the apparatus and/or to read data, especially trace data, from the apparatus. Advantageously, for instance, the apparatus can comprise at least two ports or channels, respectively. Further advantageously, each of said at least two ports or channels, respectively, can comprise an input and/or an output.

According to a further implementation form of the first aspect of the present disclosure, controlling the apparatus and/or reading data, especially trace data, from the apparatus is based on a Transfer Control Protocol (TCP) and/or an Universal Serial Bus (USB) and/or a Standard Commands for Programmable Instruments (SCPI) communication. Advantageously, for example, inefficiencies can further be reduced.

According to a further implementation form of the first aspect of the present disclosure, the power consumption monitor comprises the trigger transmitter. Advantageously, for instance, efficiency can further be increased.

According to a further implementation form of the first aspect of the present disclosure, the measurement device is configured to correct a respective drift of a corresponding clock of the apparatus and/or the measurement device especially on the basis of and/or with the aid of the log file. Advantageously, for example, accuracy can further be increased, which can analogously apply for the following implementation form.

According to a further implementation form of the first aspect of the present disclosure, the power consumption monitor is configured to a correct a respective drift of a corresponding clock of the apparatus and/or the measurement device and/or the power consumption monitor especially on the basis of and/or with the aid of the log file.

According to a further implementation form of the first aspect of the present disclosure, the measurement device comprises or is a signaling tester. Advantageously, for instance, it can efficiently be investigated what happens on the device under test after signaling an event.

According to a further implementation form of the first aspect of the present disclosure, the measurement device is used for an/or in the context of testing fifth generation communications and/or sixth generation communications. Advantageously, for example, network protocol data, especially mobile network protocol data, can efficiently be investigated.

According to a further implementation form of the first aspect of the present disclosure, the measurement device is configured to control the device under test. Advantageously, for instance, several measurements or several measurement scenarios, respectively, can be performed in an automated manner.

According to a further implementation form of the first aspect of the present disclosure, the apparatus comprises or is an apparatus without internal time. Advantageously, for example, the apparatus can especially provide measured voltage and/or current and/or power with respect to the device under test without providing the corresponding measurement time.

According to a further implementation form of the first aspect of the present disclosure, the apparatus comprises or is a power supply and/or a measurement probe. Advantageously, for instance, the measurement probe can especially be an oscilloscope probe.

According to a further implementation form of the first aspect of the present disclosure, the device under test comprises or is a mobile device, especially a cell phone or a smartphone or a tablet computer. Advantageously, for example, the measurement device can be configured to correlate network protocol data or mobile network protocol data, respectively, with respect to the mobile device with the power consumption of the mobile device.

According to a second aspect of the present disclosure, a system is provided. Said system comprises a measurement device according the first aspect of the present disclosure or any of its implementation forms, respectively, and an apparatus. In this context, the measurement device is configured to perform measurements with respect to a device under test with the aid of the apparatus. Advantageously, this allows for power trace synchronization.

According to an implementation form of the second aspect of the present disclosure, the apparatus comprises or is an apparatus without internal time. In addition to this or as an alternative, the apparatus comprises or is a power supply and/or a measurement probe. Advantageously, for instance, the apparatus can especially provide measured voltage and/or current and/or power with respect to the device under test without providing the corresponding measurement time.

According to a further implementation form of the second aspect of the present disclosure, the system further comprises the device under test preferably in the form of a mobile device, especially a cell phone or a smartphone or a tablet computer. Advantageously, for example, the measurement device can be configured to correlate network protocol data or mobile network protocol data, respectively, with respect to the mobile device with the power consumption of the mobile device.

According to a third aspect of the present disclosure, a method for performing measurements with respect to a device under test with the aid of an apparatus is provided. Said method comprises the steps of sending a trigger event to the apparatus, and logging said trigger event together with a corresponding time stamp in a log file. Advantageously, this allows for power trace synchronization.

The above description with regard to the measurement device according to the first aspect of the disclosure is correspondingly valid for the system according to the second aspect of the disclosure or the method according to the third aspect of the invention, respectively, and vice versa.

### BRIEF DESCRIPTION OF THE DRAWINGS

The above-described aspects and implementation forms of the present disclosure will be explained in the following description of specific embodiments in relation to the enclosed drawings, in which:

FIG. 1 shows a schematic diagram of a measurement device for performing measurements with respect to a device under test with the aid of an apparatus according to an embodiment;

FIG. 2 shows a schematic diagram of a measurement device for performing measurements with respect to a device under test with the aid of an apparatus according to a further embodiment;

FIG. 3 shows a schematic diagram of a system according to an embodiment of the second aspect of the present disclosure;

FIG. 4 shows a schematic diagram of a system according to a further embodiment of the second aspect of the present disclosure;

FIG. 5 shows a schematic diagram of a system according to a further embodiment of the second aspect of the present disclosure; and

FIG. 6 shows a flow diagram of a method for performing measurements with respect to a device under test with the aid of an apparatus according to an embodiment.

### DETAILED DESCRIPTIONS OF EMBODIMENTS

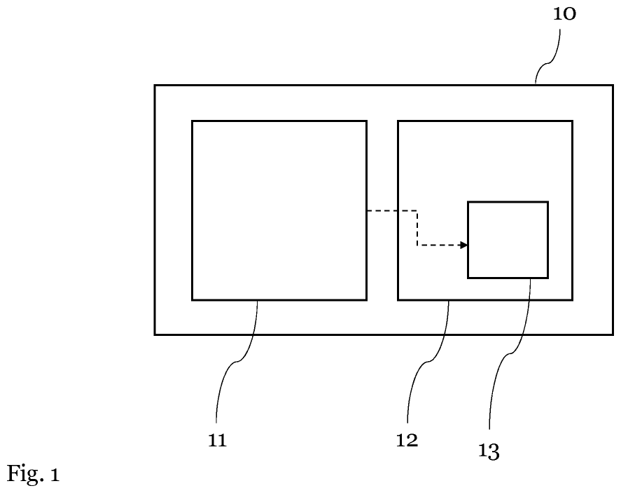

FIG. 1 illustrates an exemplary embodiment of a measurement device 10 for performing measurements with respect to a device under test with the aid of an apparatus.

Said measurement device 10 comprises a trigger transmitter 11, and a memory 12 comprising a log file 13. In this context, the trigger transmitter 11 is configured to send a trigger event to the apparatus and to log said trigger event together with a corresponding time stamp in the log file.

It is noted that said trigger event can be sent on the basis of and/or with the aid of a trigger signal. Especially as an alternative, it is further noted that the trigger event can be said trigger signal.

With respect to the trigger signal, it is noted that it might be advantageous if the trigger signal comprises or is an analog trigger signal.

It is further noted that it might advantageous if sending the trigger event to the apparatus and logging said trigger event together with a corresponding time stamp in the log file 13 are performed simultaneously.

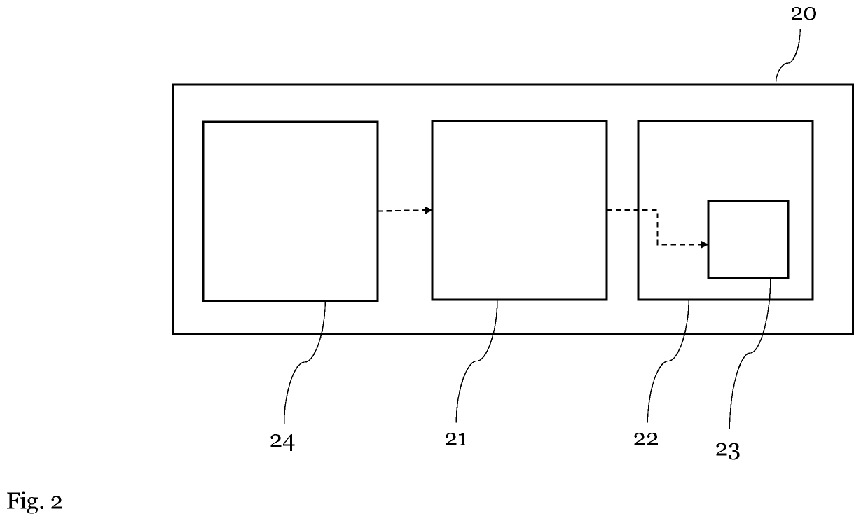

Now, with respect to FIG. 2, a further exemplary embodiment of the measurement device 20 according to the first aspect of the present disclosure is depicted.

Said measurement device 20 comprises a trigger transmitter 21, and a memory 22 comprising a log file 23, which can especially be seen as the above-mentioned trigger transmitter 11, and memory 12 comprising the log file 13 of FIG. 1. Accordingly, the corresponding explanations above can analogously apply for said trigger transmitter 21, and said memory 22 comprising said log file 23, and vice versa.

As it can be seen from FIG. 2, the measurement device 20 further comprises a power consumption monitor 24. In this context, said power consumption monitor 24 is configured to notify the trigger transmitter 21 to send the trigger event to the apparatus in intervals and to log the trigger event together with the corresponding time stamp in the log file 23.

With respect to said power consumption monitor 24, it is noted that it might be advantageous if the power consumption monitor 24 is configured to control the apparatus and/or to read data, especially trace data, from the apparatus.

It is further noted that it might be advantageous if controlling the apparatus and/or reading data, especially trace data, from the apparatus is based on a Transfer Control Protocol (TCP) and/or an Universal Serial Bus (USB) and/or a Standard Commands for Programmable Instruments (SCPI) communication.

Again, with respect to the power consumption monitor 24, it is noted that it might be advantageous if the power consumption monitor 24 comprises the trigger transmitter 21.

Furthermore, the measurement device 20 can be configured to correct a respective drift of a corresponding clock of the apparatus and/or the measurement device especially on the basis of and/or with the aid of the log file.

It might be advantageous if the measurement device 20 is configured to correct a drift between the corresponding clock of the apparatus and the corresponding clock of the measurement device. It is noted that such a clock can comprise or be an oscillator, especially an internal oscillator.

It is further noted that the measurement device 20 and/or the power consumption monitor 24 and/or the trigger transmitter 21 can comprise the respective one of a measurement device clock and/or a power consumption monitor clock and/or a trigger transmitter clock, wherein said measurement device clock and/or said power consumption monitor clock and/or said trigger transmitter clock may especially be configured to provide time information, on the basis of which the corresponding time stamp can be generated.

Moreover, with respect to the apparatus, it is noted that said apparatus can comprise an apparatus clock, wherein said apparatus clock may especially be configured such that no time stamp is generated with the aid of said apparatus clock.

It is further noted that it might be advantageous if the power consumption monitor 24 and/or the trigger transmitter 21 is configured to a correct a respective drift of a corresponding clock of the apparatus, especially of the above-mentioned apparatus clock, and/or of the measurement device 20, especially of the above-mentioned measurement device clock, and/or of the power consumption monitor, especially of the above-mentioned power consumption monitor clock, and/or of the trigger transmitter, especially of the above-mentioned trigger transmitter clock, preferably on the basis of and/or with the aid of the log file.

Furthermore, with respect to the measurement device 20, it is noted that it might be advantageous if the measurement device 20 comprises or is a signaling tester.

In addition to this or as an alternative, the measurement device 20 can be used for an/or in the context of testing fifth generation communications and/or sixth generation communications.

Further additionally or further alternatively, the measurement device 20 can be configured to control the device under test. It might be advantageous if the device under test comprises or is a mobile device, especially a cell phone or a smartphone.

Moreover, with respect to the apparatus, as indicated above, it is noted that it might be advantageous if the apparatus comprises or is an apparatus without internal time, especially without internal timestamping. Additionally or alternatively, the apparatus can comprise or be a power supply and/or a measurement probe.

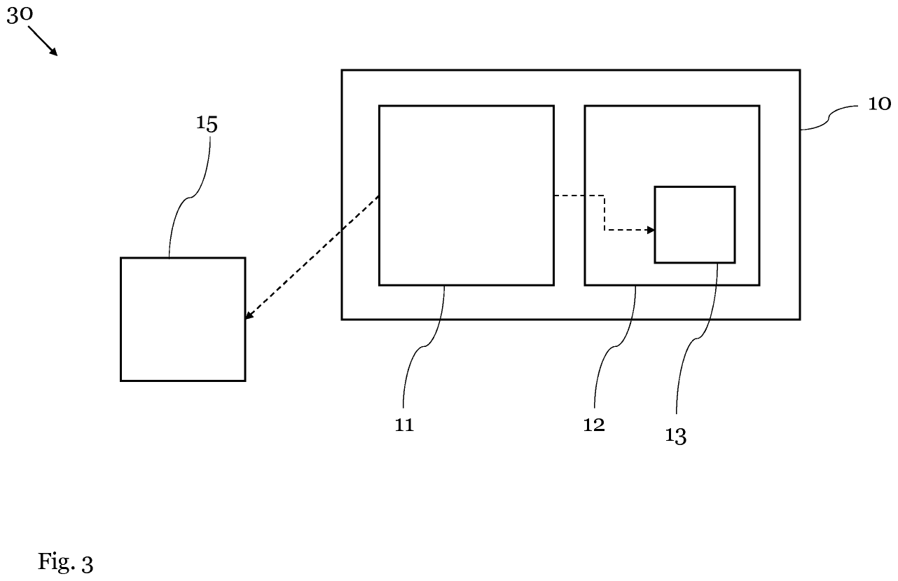

Now, with respect to FIG. 3, an exemplary embodiment of the system 30 according to the second aspect of the present disclosure is illustrated.

As it can be seen from FIG. 3, said system 30 comprises a measurement device according to the first aspect of the present disclosure, and an apparatus 15. Exemplarily, said measurement device is the above-mentioned measurement device 10 of FIG. 1. It is noted that measurement device 10 could also be replaced by the measurement device 20 of FIG. 2.

In this context, the measurement device 10 is configured to perform measurements with respect to a device under test with the aid of the apparatus 15.

With respect to said apparatus 15, it is noted the explanations above regarding the above-mentioned apparatus can analogously apply for the apparatus 15, and vice versa.

Furthermore, also with respect to said apparatus 15 or the above-mentioned apparatus, respectively, it is noted that it might be advantageous if the apparatus 15 or the above-mentioned apparatus, respectively, is configured to support the measurements performed by the measurement device 10 or by the measurement device 20, respectively. It is further noted that the apparatus 15 or the above-mentioned apparatus, respectively, can especially comprise or be a peripheral measurement device.

In addition to this or as an alternative, as already mentioned above, the apparatus 15 can comprise or be an apparatus without internal time, especially without internal timestamping. Further additionally or further alternatively, the apparatus 15 can comprise or be a power supply and/or a measurement probe.

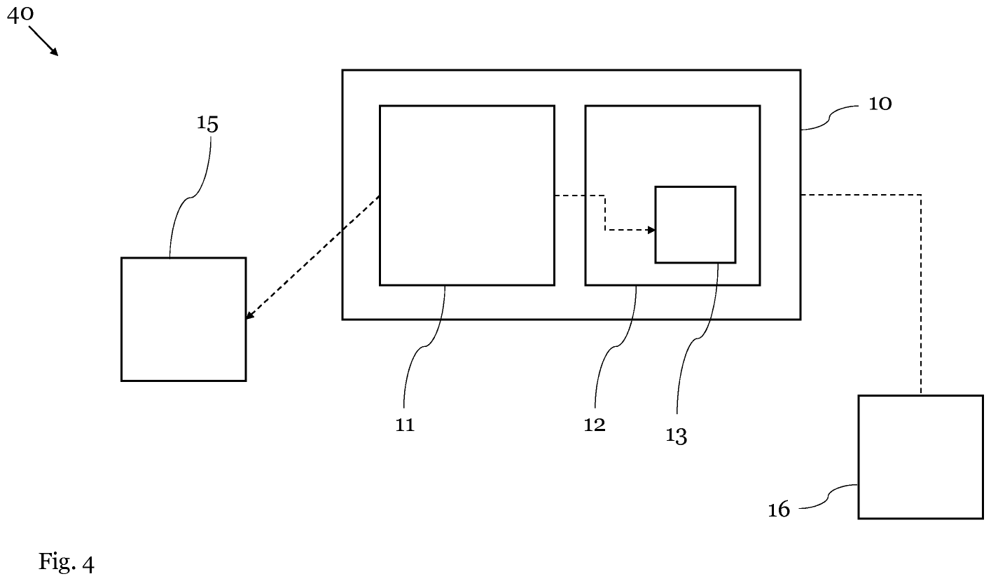

Moreover, FIG. 4 shows a further exemplary embodiment of the system 40 according to the second aspect of the present disclosure, wherein said system 40 being exemplarily based on the system 30 of Fig. further comprises the device under test 16 preferably in the form of a mobile device, especially a cell phone or a smartphone. Due to the fact that the system 40 is exemplarily based on the system 30, equivalent elements or parts, respectively, of the system 40 are not explained again but equipped with the same reference signs as done with respect to the system 30.

With respect to said device under test 16, it is noted the explanations above regarding the above-mentioned device under test can analogously apply for the device under test 16, and vice versa.

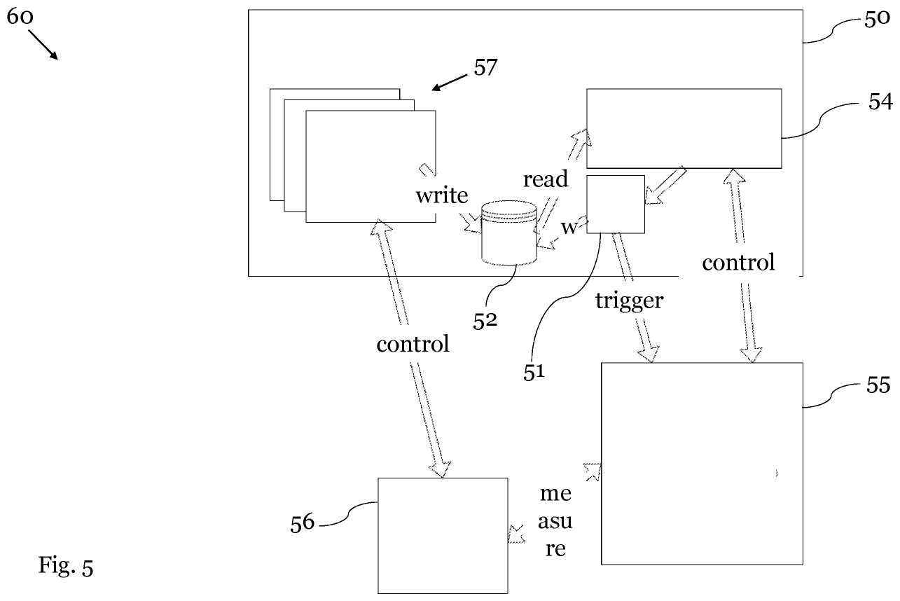

Furthermore, FIG. 5 illustrates a schematic diagram of a system 60 according to a further embodiment of the second aspect of the present disclosure.

Said system 60 exemplarily comprises a measurement device 50 according to the first aspect of the present disclosure, an apparatus 55, and a device under test 56. Said measurement device 50 is exemplarily configured for performing measurements with respect to the device under test 56 with the aid of the apparatus 55.

With respect to the measurement device 50, it is noted that the explanations above regarding the above-mentioned measurement device 10 or measurement device 20, respectively, can analogously apply for the measurement device 50, and vice versa.

Furthermore, with respect to the apparatus 55, it is noted that the explanations above regarding the above-mentioned apparatus or apparatus 15, respectively, can analogously apply for the apparatus 55, and vice versa.

Moreover, with respect to the device under test 56, it is noted that the explanations above regarding the above-mentioned device under test or device under test 16, respectively, can analogously apply for the device under test 56, and vice versa.

As it can further be seen from FIG. 5, the measurement device 50 comprises a trigger application 51, a memory 52, a power consumption application 54, and further applications 57, especially at least one measurement application.

With respect to the trigger application 51, it is noted that the explanations above regarding the above-mentioned trigger transmitter 11 or trigger transmitter 21, respectively, can analogously apply for the trigger application 51, and vice versa. It is further noted that the trigger transmitter 11 or trigger transmitter 21, respectively, can especially comprise or be a trigger application such as the trigger application 51.

With respect to the memory 52, it is noted that the explanations above regarding the above-mentioned memory 12 or memory 22, respectively, can analogously apply for the memory 52, and vice versa. Accordingly, the memory 52 can especially comprise a log file such as the log file 13 or log file 23, respectively.

With respect to the power consumption application 54, it is noted that the explanations above regarding the above-mentioned power consumption monitor 24, can analogously apply for the power consumption application 54, and vice versa. It is further noted that the power consumption monitor 24 can especially comprise or be a power consumption application such as the power consumption application 54.

It is further noted that it might be advantageous if the measurement device 50, or the measurement device 10 or 20, respectively, comprises a processor. Said processer can especially be configured to execute at least one of the trigger application 51, the power consumption application 54, the further applications 57, especially the at least one measurement application, or any combination thereof.

Again, with respect to the power consumption application 54, it is noted that said power consumption application 54 can especially be configured to control the apparatus 55 and/or to read data, preferably trace data, with respect to the apparatus 55 exemplarily via a TCP and/or USB and/or SCPI based communication.

Furthermore, the power consumption application 54 can especially be configured to notify the trigger application 51 to send a trigger event to the apparatus 55 in intervals and to log the trigger event together with the corresponding time stamp in the memory 52 or in the log file thereof, respectively.

Accordingly, the trigger application 51 may especially be configured to write at least one log to the memory 52 or the log file thereof, respectively. It is noted that the power consumption application 54 may especially be configured to read at least one log from the memory 52 or the log file thereof, respectively. It is further noted that the further applications 57, especially the at least one measurement application, can be configured to write at least one log to the memory 52 or the log file thereof, respectively.

With respect to the at least one log, it is noted that it might be advantageous if the at least one log comprises corresponding time stamps. Accordingly, the memory 52 or the log file thereof, respectively, advantageously comprises corresponding time stamps.

Again, with respect to the further applications 57, especially the at least one measurement application, it is noted that said further applications 57, especially said at least one measurement application, can exemplarily be configured to control the device under test 56.

With respect to the apparatus 55, exemplarily comprising or being a power supply and/or a measurement probe, it is noted that it might be advantageous if the apparatus comprises at least two channels, preferably four channels. It is further noted that each of said channels may especially comprise an input and/or an output.

Especially for the case that the apparatus 55 comprises or is a power supply, it might be advantageous if the apparatus 55 is configured to feedback the correspondingly applied voltage to the power consumption application 54 especially such that this information may then be logged.

It is further noted that it might be advantageous if the trigger event, exemplarily carried by an analog trigger signal, is provided for at least one or each of the at least two channels of the apparatus. It is mentioned that the measurement device 50 may especially comprise an output, preferably an analog output, via which the trigger event or the trigger signal, preferably the analog trigger signal, respectively, can be provided.

With respect to the trigger event, it is noted that it might be advantageous if the trigger event is based on a variation of the corresponding internal resistance especially of the measurement device 50. In other words, it might be advantageous if the trigger event is generated by varying the corresponding internal resistance especially of the measurement device 50.

Again, with respect to the apparatus 55, it is noted that it might be advantageous if said apparatus 55 is configured to perform at least one measurement, preferably at least one measurement regarding voltage and/or current and/or power, with respect to the device under test 56 and/or to supply the device under test 56 with power. Accordingly, it might be advantageous if the apparatus 55 is configured to support the measurements performed by the measurement device 50 especially in the sense of at least one power measurement.

Furthermore, with respect to the measurement device 50, it is noted that it might be advantageous if the measurement device 50 is configured to correlate network protocol data with respect to the device under test 56 with the power consumption of the device under test 56. Further advantageously, especially on the basis of said correlation, the measurement device 50 can be configured to investigate what time is needed for the device under test 56 to change its operating mode, especially to switch to the sleep mode, and/or what happens after an event is signaled on the device under test 56. For instance, the device under test 56 can especially be a cell phone or a smartphone or a tablet computer.

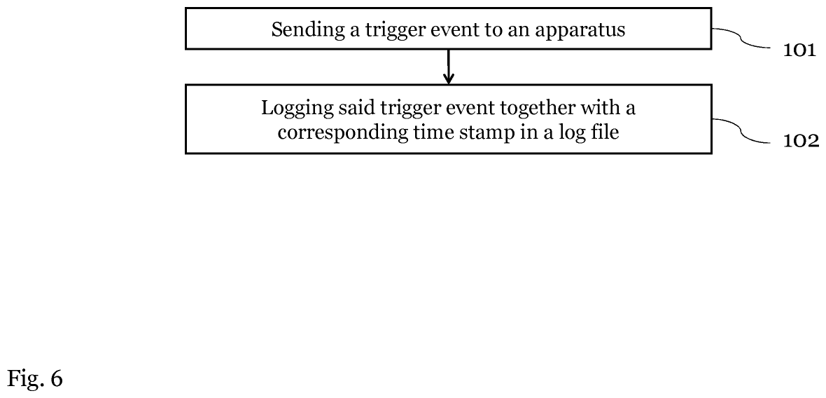

Finally, FIG. 6 illustrates a flow chart of an exemplary embodiment of the method for performing measurements, especially by a measurement device, such as the above-mentioned measurement device 10 or measurement device 20, respectively, with respect to a device under test, such as the above-mentioned device under test or device under test 16, respectively, with the aid of an apparatus, such as the above-mentioned apparatus or apparatus 15, respectively, according to the third aspect of the present disclosure.

In accordance with FIG. 6, a first step 101 exemplarily comprises sending a trigger event to the apparatus, and a second step 102 exemplarily comprises logging said trigger event together with a corresponding time stamp in a log file.

With respect to step 101, it is noted that it might be advantageous if said step 101 comprises sending a trigger event to the apparatus with the aid of a trigger transmitter, such as the above-mentioned trigger transmitter 11 or trigger transmitter 21, respectively, of the measurement device.

With respect to step 102, it is noted that it might be advantageous if said step 102 comprises logging said trigger event together with a corresponding time stamp in a log file, especially of a memory of the measurement device, such as the above-mentioned memory 12 or memory 22, respectively, with the aid of the trigger transmitter, such as the above-mentioned trigger transmitter 11 or trigger transmitter 21, respectively, of the measurement device.

It is further noted that it might be advantageous if the method further comprises the step of notifying the trigger transmitter to send the trigger event to the apparatus in intervals and to log the trigger event together with the corresponding time stamp in the log file especially with the aid of a power consumption monitor, such as the above-mentioned power consumption monitor 24, of the measurement device.

All features described above or features shown in the figures can be combined with each other in any advantageous manner within the scope of the disclosure.

What is claimed is:

1. A measurement device for performing measurements with respect to a device under test with the aid of an apparatus, the measurement device comprising:
a trigger transmitter, and
a memory comprising a log file,
wherein the trigger transmitter is configured to send a trigger event to the apparatus and to log said trigger event together with a corresponding time stamp in the log file.

2. The measurement device according to claim 1,
wherein the trigger event is sent on the basis of and/or with the aid of a trigger signal.

3. The measurement device according to claim 2,
wherein the trigger signal comprises or is an analog trigger signal.

4. The measurement device according to claim 1,
wherein sending the trigger event to the apparatus and logging said trigger event together with a corresponding time stamp in the log file are performed simultaneously.

5. The measurement device according to claim 1,
wherein the measurement device further comprises:
a power consumption monitor,
wherein the power consumption monitor is configured to notify the trigger transmitter to send the trigger event to the apparatus in intervals and to log the trigger event together with the corresponding time stamp in the log file.

6. The measurement device according to claim 5,
wherein the power consumption monitor is configured to control the apparatus and/or to read data, especially trace data, from the apparatus.

7. The measurement device according to claim 6,
wherein controlling the apparatus and/or reading data, especially trace data, from the apparatus is based on a Transfer Control Protocol (TCP) and/or an Universal Serial Bus (USB) and/or a Standard Commands for Programmable Instruments (SCPI) communication.

8. The measurement device according to claim 5,
wherein the power consumption monitor comprises the trigger transmitter.

9. The measurement device according to claim 1,
wherein the measurement device is configured to correct a respective drift of a corresponding clock of the apparatus and/or the measurement device especially on the basis of and/or with the aid of the log file.

10. The measurement device according to claim 5,
wherein the power consumption monitor is configured to a correct a respective drift of a corresponding clock of the apparatus and/or the measurement device and/or the power consumption monitor especially on the basis of and/or with the aid of the log file.

11. The measurement device according to claim 1,
wherein the measurement device comprises or is a signaling tester.

12. The measurement device according to claim 1,
wherein the measurement device is used for an/or in the context of testing fifth generation communications and/or sixth generation communications.

13. The measurement device according to claim 1,
wherein the measurement device is configured to control the device under test.

14. The measurement device according to claim 1,
wherein the apparatus comprises or is an apparatus without internal time.

15. The measurement device according to claim 1,
wherein the apparatus comprises or is a power supply and/or a measurement probe.

16. The measurement device according to claim 1,
wherein the device under test comprises or is a mobile device, especially a cell phone or a smartphone or a tablet computer.

17. A system comprising:
a measurement device according to claim 1, and
an apparatus,
wherein the measurement device is configured to perform measurements with respect to a device under test with the aid of the apparatus.

18. The system according to claim 17,
wherein the apparatus comprises or is an apparatus without internal time, and/or
wherein the apparatus comprises or is a power supply and/or a measurement probe.

19. The system according to claim 17,
wherein the system further comprises the device under test preferably in the form of a mobile device, especially a cell phone or a smartphone or a tablet computer.

20. A method for performing measurements with respect to a device under test with the aid of an apparatus, the method comprising the steps of:
sending a trigger event to the apparatus, and
logging said trigger event together with a corresponding time stamp in a log file.
